(19) United States
(12) Patent Application Publication
(10) Pub. No.: US 2009/0165721 A1
(43) Pub. Date: Jul. 2, 2009

(54) Susceptor with Support Bosses

(75) Inventors: John A. Pitney, O'Fallon, MO (US); Manabu Hamano, Utsunomiya (JP); Lance G. Hellwig, St. Louis, MO (US)

Correspondence Address: Richard A. Schuth (MEMC);Armstrong Teasdale LLP, One Metropolitan Square, Suite 2600, St. Louis, MO, 63102-2740, US

(73) Assignee: MEMC ELECTRONIC MATERIALS, INC., St. Peters, MO (US)

(21) Appl. No.: 11/965,459

(22) Filed: Dec. 27, 2007

(51) Int. Cl. C23C 16/54

(52) U.S. Cl. 118/728

(57) ABSTRACT

A susceptor for supporting a semiconductor wafer during a chemical vapor deposition process includes a body having opposing upper and lower surfaces. Support bosses extend downward from the lower face of the body. Each support boss has a boss opening sized and shaped for receiving a support post of a chemical vapor deposition device to mount the susceptor on the support post.

### BACKGROUND

The present invention generally relates to a susceptor for supporting a semiconductor wafer during a chemical vapor deposition process.

Semiconductor wafers may be subjected to a chemical vapor deposition process such as an epitaxial deposition process to grow a thin layer of silicon on the front surface of the wafer. This process allows devices to be fabricated directly on a high quality epitaxial layer. Conventional epitaxial deposition processes are disclosed in U.S. Pat. Nos. 5,904,769 and 5,769,942, which are incorporated herein by reference.

Prior to epitaxial deposition, the semiconductor wafer is loaded into a deposition chamber and lowered onto a susceptor. After the wafer is lowered onto the susceptor, the epitaxial deposition process begins by introducing a cleaning gas, such as hydrogen or a hydrogen and hydrochloric acid mixture, to a front surface of the wafer (i.e., a surface facing away from the susceptor) to pre-heat and clean the front surface of the wafer. The cleaning gas removes native oxide from the front surface, permitting the epitaxial silicon layer to grow continuously and evenly on the surface during a subsequent step of the deposition process. The epitaxial deposition process continues by introducing a vaporous silicon source gas, such as silane or a chlorinated silane, to the front surface of the wafer to deposit and grow an epitaxial layer of silicon on the front surface. A back surface opposite the front surface of the susceptor may be simultaneously subjected to hydrogen gas. The susceptor, which supports the semiconductor wafer in the deposition chamber during the epitaxial deposition, is rotated during the process to ensure the epitaxial layer grows evenly. Prior art susceptors used in epitaxial growth processes are described in U.S. Pat. Nos. 6,652,650; 6,596,095; and 6,444,027, all of which are incorporated herein by reference.

A common susceptor design includes a graphite disk having a recess in an upper face of the susceptor for receiving the wafer. The disk is coated with silicon carbide. In addition, three equally spaced, race-track-shaped openings extend into the susceptor from the lower surface for receiving the upper ends of supports disposed within the deposition chamber. These support openings engage the supports to prevent the susceptor from slipping on the supports as they turn during processing. The susceptor is prone to cracking at the locations of the race-track-shaped openings. Conventional techniques to correct this cracking problem include increasing the thickness of the carbide coating, decreasing the thickness of the carbide coating and using fillets at the inner corners of the recesses.

The applicants determined that each of the aforementioned techniques was met with limited success. Accordingly, a need exists for a susceptor that reduces or eliminates cracking due to its engagement with the support posts.

### SUMMARY

In one aspect of the present invention, a susceptor for supporting a semiconductor wafer during a chemical vapor deposition process in a chemical vapor deposition device that includes a plurality of support posts generally comprises a body having opposing upper and lower surfaces. At least one recess extends downward from the upper surface of the body for receiving a single semiconductor wafer therein during the chemical vapor deposition process. A plurality of support bosses extend downward from the lower face of the body. Each of the support bosses has a boss opening extending axially toward the lower surface of the body of the susceptor. The boss opening is sized and shaped for receiving a free end of one of the support posts of the chemical vapor deposition device to mount the susceptor on the support posts.

Other objects and features will be in part apparent and in part pointed out hereinafter.

### BRIEF DESCRIPTION OF THE DRAWINGS

FIG. 1 is a top plan of a susceptor for supporting a semiconductor wafer during a chemical vapor deposition process;

FIG. 2 is a bottom plan of the susceptor of FIG. 1;

FIG. 3A is a detail of a supporting boss of the susceptor in FIG. 2;

FIG. 3B is a fragmentary cross section of the susceptor taken along the line 3B-3B of FIG. 3A;

FIG. 3C is a fragmentary cross section of the susceptor taken along the line 3C-3C of FIG. 3A;

FIG. 4 is a cross section of a susceptor taken along the line 4-4 of FIG. 1 in combination with a semiconductor wafer; and

FIG. 5 is a schematic cross section of the susceptor of FIG. 1 supporting a semiconductor wafer in a chemical vapor deposition chamber.

Corresponding reference characters indicate corresponding parts throughout the drawings.

### DETAILED DESCRIPTION OF EXEMPLARY EMBODIMENTS

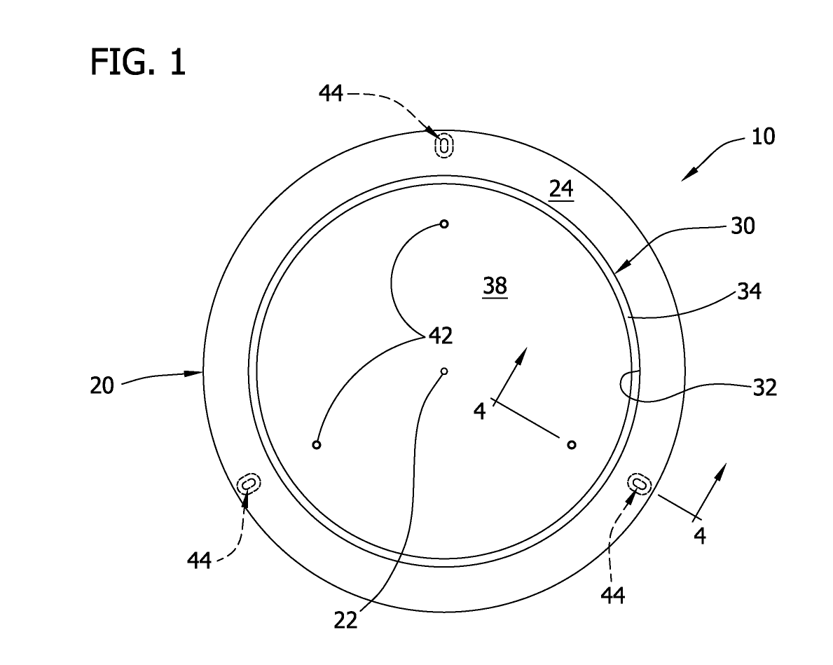

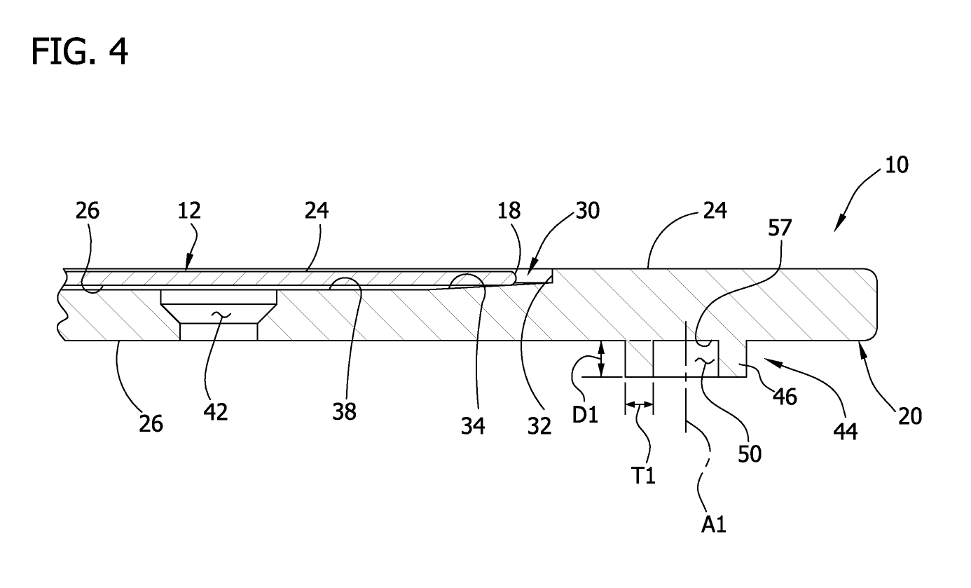

Referring now to the drawings, and in particular to FIG. 1, a susceptor is generally indicated at 10. As explained below and illustrated schematically in FIG. 4, the susceptor 10 supports a semiconductor wafer 12 in a suitable deposition chamber 14 (broadly, a chemical vapor deposition device) during a chemical vapor deposition process. More specifically and referring to FIG. 4, the chamber 14 has a plurality (e.g., three) support posts 16 extending upward within the chamber and engaging the susceptor 10 during the chemical vapor deposition process.

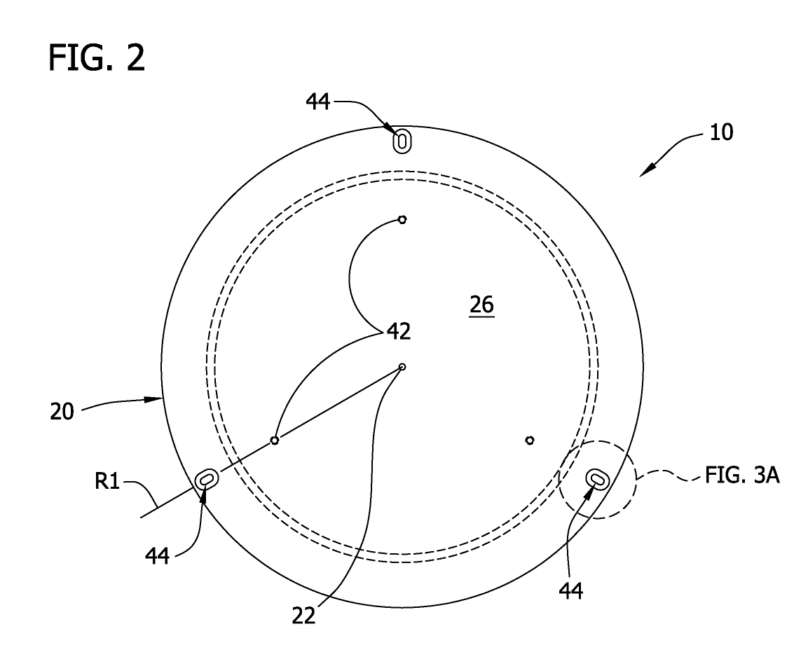

Referring to FIGS. 1 and 2, the susceptor 10 includes a disk-shaped body, generally designated by 20, having an imaginary central axis 22. Further, the body 20 includes an upper surface 24 and a lower surface 26. A first recess, generally designated by 30, extends downward into the body 20 from the upper surface 24. The first recess 30 includes a generally cylindrical wall 32 and a face 34 extending inward from a lower end of the wall 32. The face 34 also slopes downward from the wall 32 toward the central axis 22 of the body 20. The face 34 supports a wafer 12 (FIG. 4). The susceptor 10 also includes a flat surface 38 inside and below the face 34.

Referring to FIGS. 1 and 2, three equally spaced holes 42 extend through the susceptor 10 at the surface 38. These holes 42 receive conventional lift pins (not shown) to raise the wafer 12 above the susceptor 10 and lower it onto the susceptor during processing. As these holes 42 and the lift pins are well known in the art, they will not be described in further detail.

Although the susceptor body 20 may have other overall dimensions without departing from the scope of the present invention, in one embodiment the susceptor has an overall diameter of about 14.7 inches. Further, although the susceptor body 20 may be made of other materials without departing from the scope of the present invention, in one embodiment the susceptor body is made of silicon carbide coated graphite. The susceptor body 20 may have a plurality of holes extending from the upper surface 14 to the lower surface 16 as shown and described in U.S. Pat. Nos. 6,652,650 and 6,444,027. It is understood that the susceptor body may take on other configurations than those detailed above. For example, the susceptor body 20 may have a large central opening. Other configurations of the susceptor body that deviate from the above description are within the scope of the present invention.

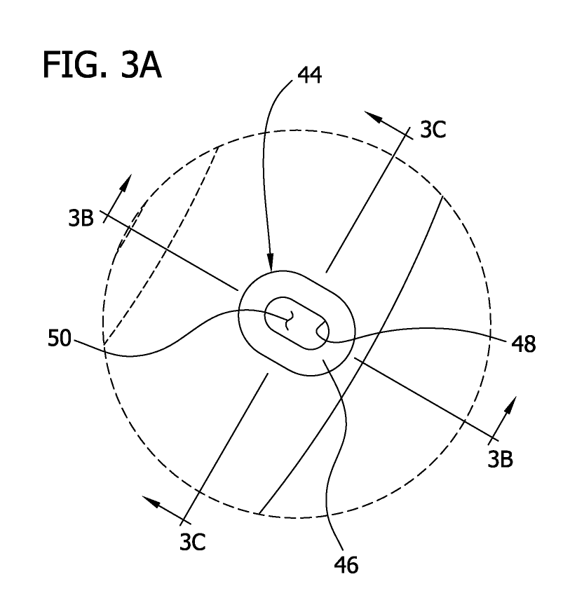

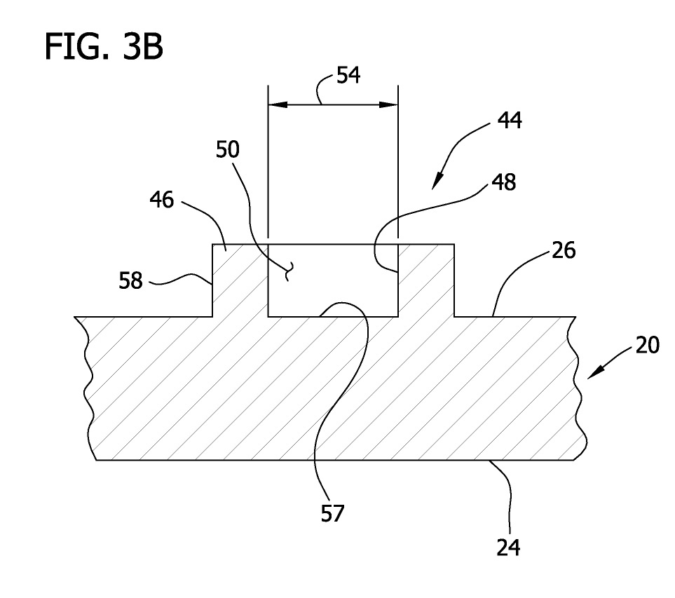

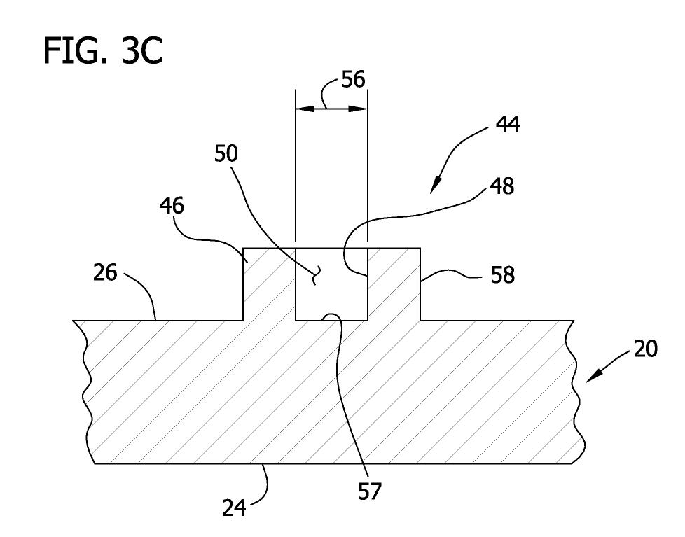

Referring to FIGS. 1 and 2, three equally spaced support bosses, generally indicated at 44, extend outward from the lower surface 26 of the susceptor body 20. With reference to FIGS. 3A-3C and 4, one of the bosses 44 is shown in detail, and reference is made to this boss with respect to the below description with the understanding that the structure of each of the bosses is identical. The boss 44 includes a wall 46 with an interior peripheral surface 48 defining an oblong or race-track-shaped opening 50 extending axially (i.e., along imaginary axis A1—FIG. 4) toward the lower surface 26 of the susceptor body 20. The opening 50 may have other shapes without departing from the scope of the invention. The opening 50 is sized and shaped to receive a free end of one of the support posts 16 of a deposition chamber 14, as will be described below.

Each boss opening 50 has a major diameter 54 (FIG. 3B) and a minor diameter 56 (FIG. 3C). In the illustrated embodiment and as shown in FIG. 2, the major diameter 54 of each opening 50 is coextensive with an imaginary radial line R1 of the susceptor 10. The boss opening 50 may have a different orientation with respect to the susceptor 10 without departing from the scope of the invention. As an example and without out limitation, the major diameter 54 of each boss opening 50 may be about 0.8 cm (0.3 in) and the minor diameter 56 may be about 0.5 cm (0.2 in).

Referring to FIG. 4, each boss opening 50 also has a depth D1 extending toward the lower surface 26 of the susceptor body 20 to a lower surface 57 of the boss 44. As an example and without limitation, the depth D1 of each boss opening 50 may be about 0.15 cm (0.06 in). Further, it is contemplated that the lower surfaces 57 of each boss 44 may be generally coplanar with the lower surface 26 of the susceptor body 20.

In the illustrated embodiment, the wall 46 of the boss 44 has an exterior peripheral surface 58 that is oblong or generally race-track-shaped and is generally concentric with the interior peripheral 48 surface of the wall. The wall 46 has a thickness T1 between the interior and exterior peripheral surfaces 46, 58, respectively, that is generally uniform around the axis A1 of the boss opening 50. As an example and without limitation, the thickness T1 of each boss wall 46 may be about 0.15 cm (0.06 in). It is understood that the exterior peripheral surfaces 58 of the walls 46 may be other shapes and the thicknesses of the walls may be non-uniform.

Although the bosses 44 10 may be made of other materials without departing from the scope of the present invention, in one embodiment the bosses are made of silicon carbide coated graphite. The bosses 44 may be formed integrally with the susceptor body 20, such as by machining the bosses and the susceptor body from a single blank of graphite. It is understood that the bosses 44 may be formed separate from the susceptor body 20 and subsequently secured thereto. Other ways of forming the susceptor 10 having the bosses 44 are within the scope of the invention. It is also contemplated that fillets may be formed at internal and external corners where the bosses 44 meet the susceptor body to increase load-bearing capabilities of the bosses.

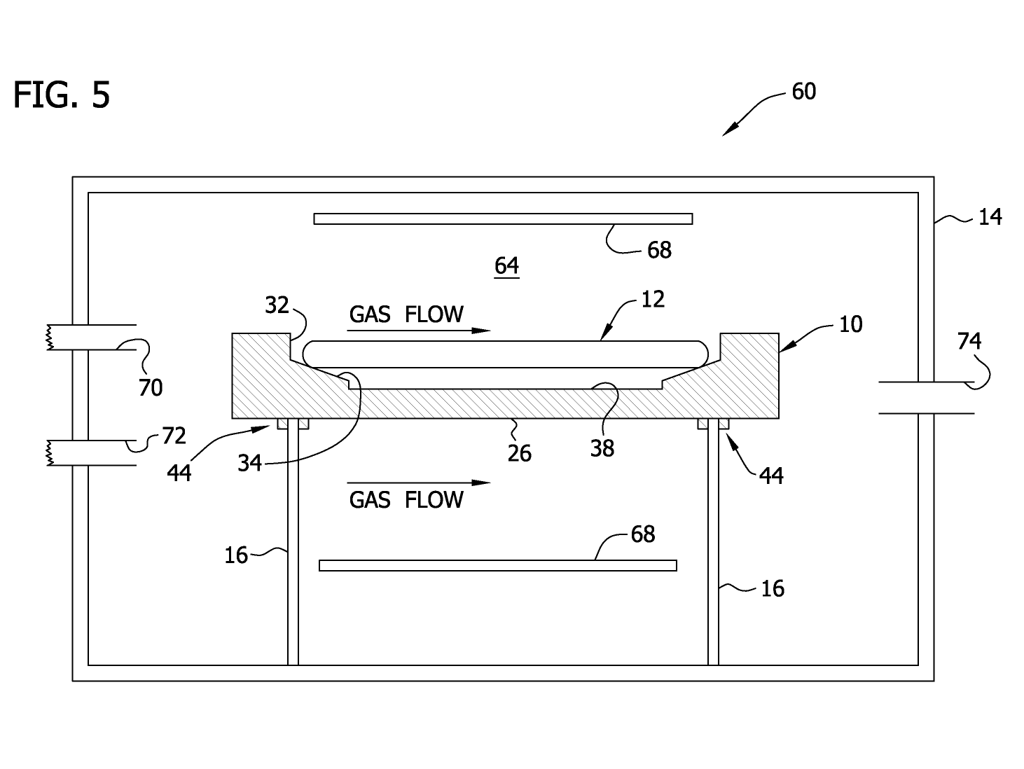

Referring to FIG. 5, the susceptor 10 described above may be used as part of an apparatus, generally indicated at 60, for chemical vapor deposition processes such as an epitaxial deposition process. In the illustrated embodiment, the apparatus 60 includes the epitaxial reaction chamber 14, mentioned above, having an interior volume or space 64. The susceptor described above is sized and shaped for receipt within the interior space 64 of the chamber 14 and for supporting the semiconductor wafer 12. The susceptor 10 is attached to the conventional support posts 16 by inserting the ends of the posts into the openings 50 in the support bosses 44. As is generally known to those having ordinary skill in the art, the support posts 16 rotate the susceptor 10 during the epitaxial process. The reaction chamber 14 also contains a heat source, for example heating lamp arrays 68 located above and below the susceptor 10 for heating the wafer 12 during an epitaxial deposition process. An upper gas inlet 70 and lower gas inlet 72 allow gas to be introduced into the interior space 64 of the chamber 14.

During the epitaxial deposition process, an epitaxial silicon layer grows on the front surface of the semiconductor wafer 12. The wafer 12 is introduced into the chamber 14 and centered on the face 34 of the susceptor 10. First the apparatus performs a pre-heat or cleaning step. A cleaning gas, such as hydrogen or a mixture of hydrogen and hydrochloric acid, is introduced into the chamber 14 at about ambient pressure, at a temperature from about 1000° C. to about 1250° C., and at a flow rate from about five liters per minute to about 100 liters per minute. After a period of time sufficient to remove native oxide layers from both the front and back surfaces of the wafer 12 and to stabilize the temperature in the reaction chamber 14 from about 1000° C. to about 1250° C., a silicon-containing source gas, such as silane or a chlorinated silane, is introduced through the inlet 70 above the front surface of the wafer 12 at a flow rate from about one liter per minute to about fifty liters per minute. The source gas flow continues for a period of time sufficient to grow an epitaxial silicon layer on a front or upper surface of the wafer 12 to a thickness from about 0.1 micrometer to about 200 micrometers. Simultaneously with the source gas being introduced, a purge gas, such as hydrogen, flows through the inlet 72 below the back or lower surface of the wafer 12. The purge gas flow rate is selected so the purge gas contacts the back surface of the semiconductor wafer 12 and carries out-diffused dopant atoms from the back surface to an exhaust outlet 74.

The support bosses 44 of the susceptor 10 replace the conventional support openings formed in the body of susceptor. Accordingly, the susceptor 10 having support bosses 44 does not have thinned locations due to the formation of the support recesses. Therefore, cracking of the susceptor due to these thinned locations is precluded.

When introducing elements of various aspects of the present invention or embodiments thereof, the articles “a”, “an”, “the” and “said” are intended to mean that there are one or more of the elements. The terms “comprising”, “including” and “having” are intended to be inclusive and mean that there may be additional elements other than the listed elements. Moreover, the use of “top” and “bottom”, “front” and “rear”, “above” and “below” and variations of these and other terms of orientation is made for convenience, but does not require any particular orientation of the components.

As various changes could be made in the above constructions, methods and products without departing from the scope of the invention, it is intended that all matter contained in the above description or shown in the accompanying drawings shall be interpreted as illustrative and not in a limiting sense. Further, all dimensional information set forth herein is exemplary and is not intended to limit the scope of the invention.

1. A susceptor for supporting a semiconductor wafer during a chemical vapor deposition process in a chemical vapor deposition device that includes a plurality of support posts, the susceptor comprising:
a body having opposing upper and lower surfaces,
at least one recess extending downward from the upper surface of the body for receiving a single semiconductor wafer therein during the chemical vapor deposition process,
a plurality of support bosses extending downward from the lower face of the body, each of said support bosses having a boss opening, wherein the boss opening is sized and shaped for receiving a free end of one of the support posts of the chemical vapor deposition device to mount the susceptor on the support posts.

2. A susceptor as set forth in claim 1 wherein each boss opening is generally oblong.

3. A susceptor as set forth in claim 2 wherein each boss opening has major and minor diameters.

4. A susceptor as set forth in claim 3 wherein the major diameter of the boss openings are along a radius of the susceptor.

5. A susceptor as set forth in claim 3 wherein the major diameter of each boss opening is about 0.3 in and the minor diameter of each boss opening is about 0.2 in.

6. A susceptor as set forth in claim 2 wherein each support boss includes a wall having an interior surface defining the boss opening, and an exterior surface.

7. A susceptor as set forth in claim 6 wherein the wall has a thickness extending between interior and exterior surfaces of the wall, and wherein the thickness of each wall is generally uniform.

8. A susceptor as set forth in claim 7 wherein the thickness of the wall of each support boss is about 0.06 in.

9. An apparatus for conducting a chemical vapor deposition process, the apparatus comprising:
a reaction chamber,
a plurality of support posts disposed in the chamber,
a susceptor for supporting a semiconductor wafer during the chemical vapor deposition process, the susceptor disposed in the reaction chamber, the susceptor comprising:
a body having opposing upper and lower surfaces,
a plurality of support bosses extending downward from the lower face of the body, each of said support bosses having a boss opening, wherein at least a free end of the support post is received within the boss opening to mount the susceptor on the support posts.

10. An apparatus as set forth in claim 9 wherein each boss opening is generally oblong.

11. An apparatus as set forth in claim 10 wherein each boss opening has major and minor diameters.

12. An apparatus as set forth in claim 11 wherein the major diameter of the boss openings are coextensive with a radius of the susceptor.

13. An apparatus as set forth in claim 11 wherein the major diameter of each boss opening is about 0.3 in and the minor diameter of each boss opening is about 0.2 in.

14. An apparatus as set forth in claim 10 wherein each support boss includes a wall having an interior surface defining the boss opening, and an exterior surface that is generally concentric with the interior surface.

15. An apparatus as set forth in claim 13 wherein the wall has a thickness extending between interior and exterior surfaces of the wall, and wherein the thickness of each wall is generally uniform.

16. An apparatus as set forth in claim 15 wherein the thickness of the wall of each support boss is about 0.06 in.

17. An apparatus as set forth in claim 9 further comprising at least one recess extending downward from the upper surface of the body for receiving a single semiconductor wafer therein.
